(19) United States
(12) Patent Application Publication
(10) Pub. No.: US 2003/0111673 A1
(43) Pub. Date: Jun. 19, 2003

(54) Semiconductor integrated circuit

(76) Inventor: Masahiro Shiina, Ora-gun (JP)

Correspondence Address: Barry E. Bretschneider, Morrison & Foerster LLP, Suite 300, 1650 Tysons Boulevard, McLean, VA, 22102, US

(21) Appl. No.: 10/291,767

(22) Filed: Nov. 12, 2002

(30) Foreign Application Priority Data
Nov. 12, 2001 (JP) 2001-345710
Nov. 21, 2001 (JP) 2001-356137

(51) Int. Cl. H01L 27/10

(52) U.S. Cl. 257/208

(57) ABSTRACT

Desired circuit characteristics are obtained by realizing a layout considering symmetry of semiconductor elements in a circuit block. Emitter follower circuits are disposed close to a differential amplifier and symmetrically with respect to a center line of the differential amplifier. Bipolar transistors in the emitter follower circuits are disposed close to bipolar transistors in the differential amplifier with difference in orientation by 90 degrees or 270 degrees. Hereby symmetry of the differential amplifier in the emitter follower circuits is improved to have better circuit characteristics, as the interconnections from the differential amplifier to the emitter follower circuits are kept from intersecting with each other and can be made equal in length.

### BACKGROUND OF THE INVENTION

1. Field of the Invention

This invention relates to a semiconductor integrated circuit, specifically to a technology for improving characteristics of the circuit by securing symmetry of design.

2. Description of the Related Art

A prior art semiconductor integrated circuit structure will be explained taking a differential amplifier, which is frequently used in bipolar linear integrated circuits, as an example.

In the basic structure of the differential amplifier 11, both emitters of a first transistor Q11 and a second transistor Q12 are connected to a constant current transistor Q13, and each of the collectors of the transistors Q11 and Q12 is connected to a power supply Vcc through load resistors R11 and R12, respectively, as shown in FIG. 8.

Compensating variable factors of the transistors to suppress their effects on an output is made possible by amplifying the difference between signals Vin1 and Vin2, which are respectively applied to bases of the transistors Q11 and Q12, the bases serving as input terminals, and creating output signals Vout1 and Vout2 from collectors of the transistors Q11 and Q12, respectively.

Attention is paid to secure pair matching of the transistors Q11 and Q12 as well as pair matching of the load resistors R11 and R12, since a midpoint potential of the output would shift, resulting in a loss of desired circuit characteristics, if balance between elements is lost. Here the pair matching means uniformity in the characteristics of the elements forming the pair.

However, even though attention is paid to secure the pair matching of the transistors Q11 and Q12, as well as the pair matching of the load resistors R11 and R12 in the above mentioned circuit, there are problems, which are described below, when the circuit is laid out to dispose each of the semiconductor elements according to a circuit diagram, for instance from left to right (or from right to left).

That is, each of emitter follower circuits 12 and 13 connected to each of the pair of differential outputs of the differential amplifier 11 is disposed to right side of a center line of the differential amplifier 11, as shown in FIG. 8.

The emitter follower circuit 12 includes a transistor Q14, a constant current transistor Q16 and an emitter resistance R13 of the constant current transistor Q16. Also, the emitter follower circuit 13 includes a transistor Q15, a constant current transistor Q17 and an emitter resistor R14 of the constant current transistor Q17.

Thus, symmetry of the semiconductor integrated circuit including the differential amplifier 11 is lost, resulting in a loss of desired circuit characteristics. For example, length of an interconnection, inputting the output from the differential amplifier 11 to a base of a transistor Q14 of the emitter follower circuit 12, differs from length of an interconnection inputting the output from the differential amplifier 11 to a base of a transistor Q15 of the emitter follower circuit 13, and thus the desired characteristics might not be obtained because of the offset due to impedance.

Also, an interconnection between the differential amplifier 11 and the emitter follower circuit 12 intersects with a collector node of the transistor Q12, and an interconnection between the differential amplifier 11 and the emitter follower circuit 13 intersects with an emitter node of the transistor Q14 of the emitter follower circuit 12, resulting in deterioration of high frequency characteristics.

### SUMMARY OF THE INVENTION

An integrated circuit of this invention includes a circuit block having a plurality of semiconductor elements and a pair of emitter follower circuits which are connected to the circuit block, wherein the pair of emitter follower circuits is disposed close to the circuit block and symmetrically with respect to a center line of the circuit block.

Hereby, symmetry of the circuit block including the emitter follower circuits is improved to have better circuit characteristics, as the interconnections from output terminals of the circuit block to the emitter follower circuits are kept from intersecting with each other and can be made equal in length.

### BRIEF DESCRIPTION OF THE DRAWINGS

FIG. 1 shows a circuit diagram of a semiconductor integrated circuit according to a first embodiment of the invention.

FIG. 2 shows a layout of the semiconductor integrated circuit according to the first embodiment of the invention.

FIG. 3 shows a circuit diagram of a semiconductor integrated circuit according to a second embodiment of the invention.

FIG. 4 shows a layout of the semiconductor integrated circuit according to the second embodiment of the invention.

FIG. 5 shows a circuit diagram of a semiconductor integrated circuit according to a third embodiment of the invention.

FIG. 6 shows a circuit diagram of a semiconductor integrated circuit according to a fourth embodiment of the invention.

FIG. 7A shows a layout of the semiconductor integrated circuit according to the fourth embodiment of the invention.

FIG. 7B shows a layout of the semiconductor integrated circuit according to the fourth embodiment of the invention.

FIG. 8 shows a circuit diagram of a semiconductor integrated circuit according to the prior art.

### DETAILED DESCRIPTION OF THE INVENTION

The first embodiment of this invention will be explained referring to the figures hereinafter.

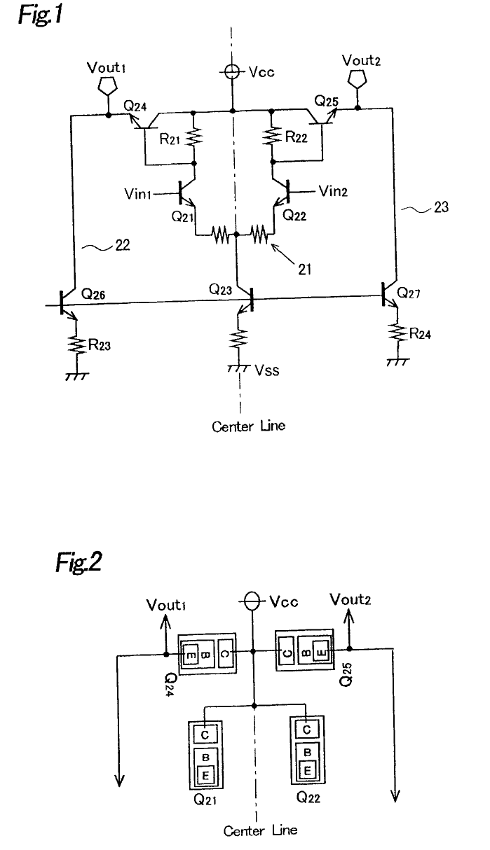

FIG. 1 is a circuit diagram of a differential amplifier 21, and FIG. 2 is a layout of the differential amplifier 21. The circuit diagram of FIG. 1 also represents a physical configuration of transistors and interconnections.

In the differential amplifier 21, both emitters of a first transistor Q21 and a second transistor Q22 are connected to a constant current transistor Q23, and each of collectors of the transistors Q21 and Q22 is connected to a power supply Vcc through each of load resistors R21 and R22, respectively, as shown in FIG. 1.

Compensating variable factors of the transistors to suppress their effects on outputs is made possible by amplifying the difference between signals Vin1 and Vin2 applied to bases of the transistors Q21 and Q22, which are input terminals, and getting output signals Vout1 and Vout2 from collectors of the transistors Q21 and Q22.

Further, each of emitter follower circuits 22 and 23 is connected with each of the collectors of the transistors Q21 and Q22, respectively. Here, the emitter follower circuit 22 includes a transistor Q24, a constant current transistor Q26 and an emitter resistor R23 of the constant current transistor Q26. Similarly, the emitter follower circuit 23 includes a transistor Q25, a constant current transistor Q27 and an emitter resistor R24 of the constant current transistor Q27.

And the emitter follower circuits 22 and 23 are disposed close to the differential amplifier 21 and symmetrically with respect to a center line of the differential amplifier 21.

More specifically, bipolar transistors Q24 and Q25, included in the emitter follower circuits 22 and 23, are disposed close to the bipolar transistors Q21 and Q22, included in the differential amplifier Q21, and orientation of emitter-collector of Q24 and Q25 is different from that of Q21 and Q22 by 90 degrees or 270 degrees, as shown in FIG. 2. References C, B and E in FIG. 2 represent a collector, a base and an emitter of a bipolar transistor, respectively.

Symmetry of the differential amplifier 21, included in the emitter follower circuits 22 and 23, is improved to have better circuit characteristics, as the interconnections from the differential amplifier 21 to the emitter follower circuits 22 and 23 are kept from intersecting with each other and can be made equal in length by adopting the circuit structure.

Next, a second embodiment of this invention will be explained referring to the figures hereinafter.

In the second embodiment, the invention is applied to a double differential amplifier or so-called Gilbert cell.

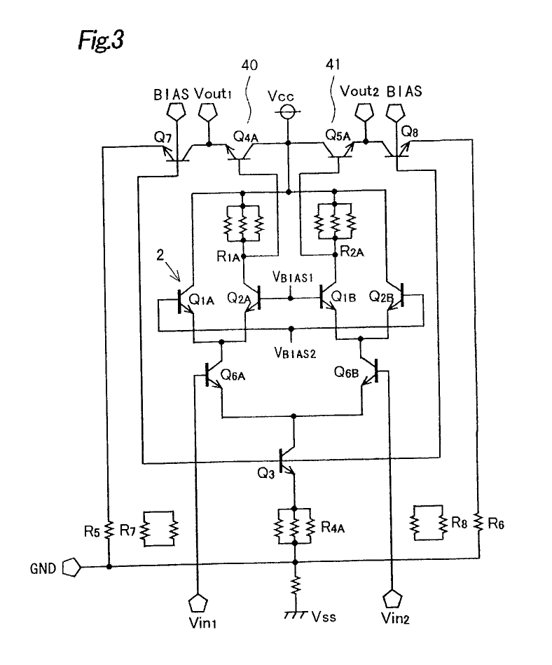

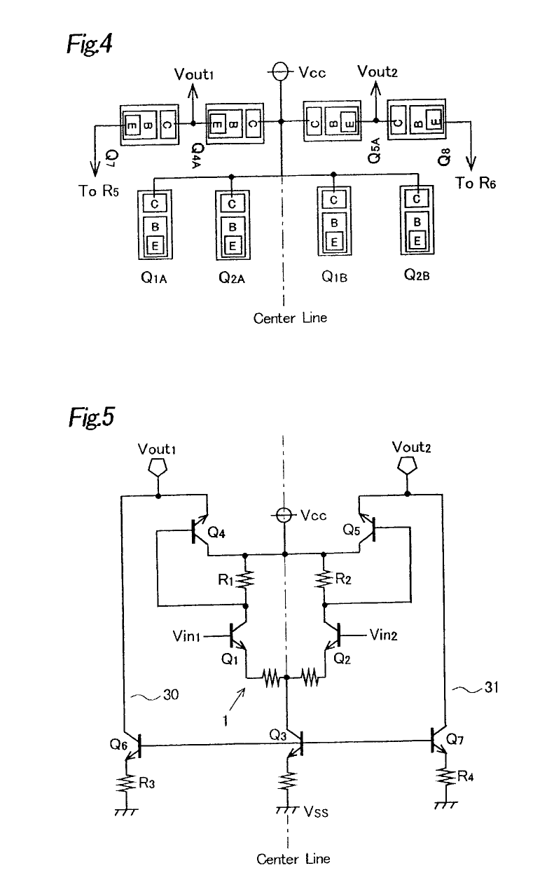

FIG. 3 is a circuit diagram of the double differential amplifier 2, and FIG. 4 is a layout of the double differential amplifier 2. The circuit diagram of FIG. 3 also represents physical configuration of transistors and interconnections. References C, B and E in FIG. 4 represent a collector, a base and an emitter of a bipolar transistor, respectively. Resistors R1A and R2A and other components are not shown in the figure for convenience.

Both emitters of a first transistor Q1A and a second transistor Q2A are connected to a collector of an input transistor Q6A, both emitters of a third transistor Q1B and a fourth transistor Q2B are connected to a collector of an input transistor Q6B, both emitters of the input transistors Q6A and Q6B are connected to a constant current transistor Q3 and each of collectors of the transistors Q2A and Q1B is connected to the power supply Vcc through each of load resistors R1A and R2A, respectively, forming a basic structure. Each of the collectors of the transistors Q1A, Q2A, Q1B and Q2B can be connected to the power supply Vcc through a load resistor instead.

Compensating variable factors of the transistors to suppress their effects on outputs is made possible by amplifying the difference between signals Vin1 and Vin2 applied to bases of the transistors Q6A and Q6B, which are input terminals, and getting output signals Vout1 and Vout2 from the collectors of the transistors Q2A and Q1B through emitter follower circuits 40 and 41. Transistors Q7 and Q8 are constant current transistors and R5 and R6 are resistors of the emitter follower circuits 40 and 41.

The emitter follower circuits 40 and 41 are disposed close to the double differential amplifier 2 and symmetrically with respect to a center line (not shown) of the double differential amplifier 2.

More specifically, transistors Q4A, Q7, Q5A and Q8, included in the emitter follower circuits 40 and 41, are disposed close to the double differential amplifier 2, and their orientation differ by 90 degrees or 270 degrees from the orientation of those included in the double differential amplifier 2, as shown in FIG. 4.

Hereby, symmetry of the circuit can be improved, and the characteristics of an integrated circuit can be improved when the invention is applied to a circuit such as the double differential amplifier 2, which prefers symmetry of signals.

When the invention is applied to a circuit such as the double differential amplifier 2, which prefers symmetry of signals, the characteristics of the integrated circuit can be improved, especially because disposing the emitter follower circuits 40 and 41 close to the double differential amplifier 2 and symmetrically with respect to the center line of the double differential amplifier 2 shortens interconnections from the double differential amplifier 2 to the emitter follower circuits 40 and 41, leading to suppressing variations in signal transfer due to the elongated interconnections, and also to reducing impedance of the interconnections.

Symmetry in semiconductor elements is further improved to have better circuit characteristics, by also disposing the constant current transistors Q7 and Q8 of the emitter follower circuits 40 and 41 close to the differential amplifier 2, as shown in FIG. 3 and FIG. 4.

Resistors R5, R6, R7 and R8 and capacitors (not shown), which are for trimming, are also disposed symmetrically with respect to the center line of the double differential amplifier 2, so that the characteristics of the circuit are maintained by maintaining symmetry when these resistors or the capacitors are used.

Next, a third embodiment of this invention will be explained referring to the figures hereinafter.

In a differential amplifier 1, both emitters of a first transistor Q1 and a second transistor Q2 are connected to a constant current transistor Q3, and each of collectors of the transistors Q1 and Q2 is connected to a power supply Vcc through each of load resistors RI and R2, respectively, as shown in FIG. 5. The circuit diagram of FIG. 5 also represents physical configuration of transistors and interconnections.

Compensating variable factors of the transistors Q1 and Q2 to suppress their effects on outputs is made possible by amplifying the difference between signals Vin1 and Vin2 applied to bases of the transistors Q1 and Q2, which are input terminals, and getting output signals Vout1 and Vout2 from the collectors of the transistors Q1 and Q2.

In addition, a pair of emitter follower circuits 30 and 31 connected with the collectors of the transistors Q1 and Q2, which are output terminals of the differential amplifier 1, is disposed close to the differential amplifier 1 and symmetrically with respect to a center line of the differential amplifier 1.

Further, bipolar transistors Q4 and Q5, included in the emitter follower circuits 30 and 31, are disposed in the same orientation as the bipolar transistors Q1 and Q2, included in the differential amplifier 1. That is, an emitter, a base and a collector of each of the transistors Q4 and Q5 are aligned vertically, and an emitter, a base and a collector of each of the transistors Q1 and Q2, included in the differential amplifier 1, are also aligned vertically.

Alternatively, an emitter, a base and a collector of each of the transistors Q4 and Q5, included in the emitter follower circuits 30 and 31, can be aligned in a different (180 degrees rotated) orientation from that of an emitter, a base and a collector of each of the transistors Q1 and Q2, included in the differential amplifier 1. For example, the emitter, the base and the collector of the bipolar transistor Q4 are aligned from top to bottom, while the collector, the base and the emitter of the bipolar transistor Q1 are aligned from top to bottom.

The configuration mentioned above better accommodates variations in production due to an error in mask alignment or other factors, and further improves the characteristics of the circuit, compared with the configuration of the first embodiment shown in FIG. 1, in which the orientation of the bipolar transistors Q24 and Q25, included in the emitter follower circuits 22 and 23, is different from that of the bipolar transistors Q21 and Q22, included in the differential amplifier 21, by 90 degrees. That is, the error in mask alignment occurs only in vertical alignment with the configuration of the third embodiment, while the error occurs in both vertical and horizontal alignments with the configuration of the first embodiment, where the orientation of the bipolar transistors Q24 and Q25, included in the emitter follower circuits 22 and 23, is different from that of the bipolar transistors Q21 and Q22, included in the differential amplifier 21, by 90 degrees.

Next, a fourth embodiment of this invention will be explained referring to the figures hereinafter.

In the fourth embodiment, the invention is applied to a double differential amplifier or so-called Gilbert cell.

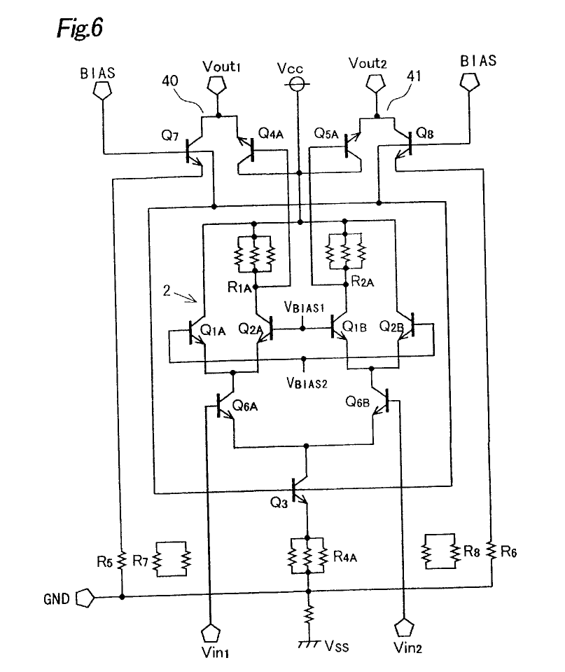

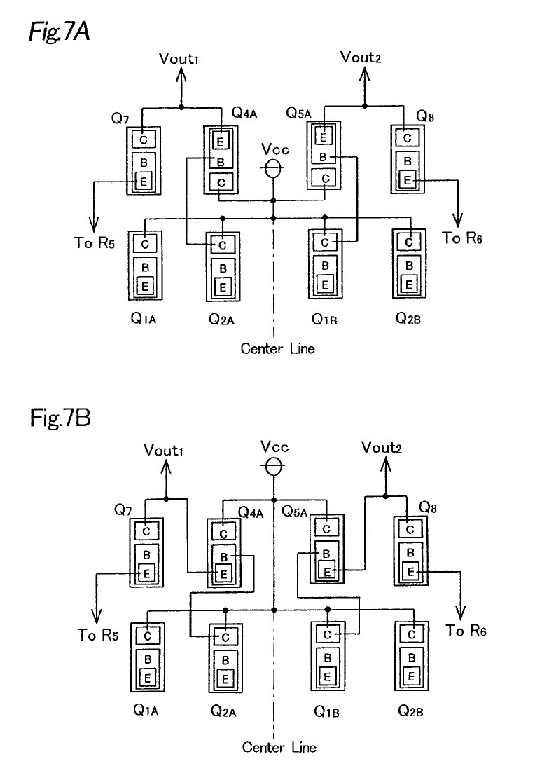

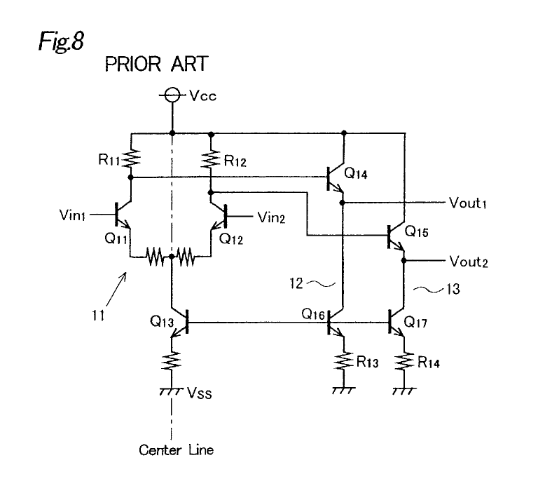

FIG. 6 is a circuit diagram of the double differential amplifier 2, and FIG. 7 is a layout of the double differential amplifier 2. References C, B and E in FIG. 7 represent a collector, a base and an emitter of a bipolar transistor, respectively. Resistors R1A and R2A and other components are not shown in the figure for convenience. FIG. 6 also represents a physical configuration of transistors and interconnections.

Explanation on the circuit structure of the double differential amplifier 2 is omitted, since it is the same as that of the second embodiment.

Emitter follower circuits 40 and 41 connected with collectors of transistors Q2A and Q1B of the double differential amplifier 2 are disposed close to the double differential amplifier 2 (above the double differential amplifier 2 in this embodiment, as it is closer to the double differential amplifier 2) and symmetrically with respect to a center line of the differential amplifier 2, while an emitter, a base and a collector of each of bipolar transistors Q4A and Q5A, included in the emitter follower circuits 40 and 41, are disposed parallel but in inverse orientation, or rotated by 180 degrees, with those of each of bipolar transistors Q1A, Q2A, Q1B and Q2B, included in the differential amplifier 2.

When the invention is applied to a circuit such as the double differential amplifier 2, which prefers symmetry of signals, the characteristics of the integrated circuit can be improved, because disposing the emitter follower circuits 40 and 41 close to the double differential amplifier 2 and symmetrically with respect to the center line of the double differential amplifier 2 improves symmetry of the circuit structure.

When the invention is applied to a circuit such as the double differential amplifier 2, which prefers symmetry of signals, the characteristics of the integrated circuit can be improved, especially because disposing the emitter follower circuits 40 and 41 close to the double differential amplifier 2 and symmetrically with respect to the center line of the double differential amplifier 2 shortens interconnections from the double differential amplifier 2 to the emitter follower circuits 40 and 41, thereby suppressing variations in signal transfer due to the elongated interconnections, and also to reducing impedance of the interconnections.

Symmetry in semiconductor elements is further improved to have better circuit characteristics by also disposing the constant current transistors Q7 and Q8 of the emitter follower circuits 40 and 41 close to the differential amplifier 2, as shown in FIG. 7A.

The characteristics of the circuit can be improved by disposing the constant current transistors Q7 and Q8 in the same orientation as the bipolar transistors Q1A, Q2A, Q1B and Q2B, included in the double differential amplifier 2, since symmetry in each of the constant current transistors Q7 and Q8 and the bipolar transistors Q1A, Q2A, Q1B and Q2B, included in the double differential amplifier 2, is improved. The symmetry is further improved because the emitter, the base and the collector of each of the constant current transistors Q7 and Q8 and the bipolar transistors Q1A, Q2A, Q1B and Q2B, included in the double differential amplifier 2, are aligned from top to bottom in the same order as each other.

Additionally, the bipolar transistors Q4A and Q5A, included in the emitter follower circuits 40 and 41, can be disposed in the same orientation as the bipolar transistors Q1A, Q2A, Q1B and Q2B as well as the emitter, the base and the collector of each of the transistors are aligned from top to bottom in the same order as each other as shown in FIG. 7B, so that the semiconductor integrated circuit is less vulnerable to variations in production such as mask alignment errors.

Further, with a circuit configuration shown in FIG. 7A, each of the bipolar transistors Q1A, Q2A, Q1B and Q2B, included in the double differential amplifier 2, and each of the emitter follower circuits 40 and 41 can be connected to a power supply Vcc with a minimum length of interconnections, realizing a semiconductor integrated circuit with reduced impedance compared with a circuit shown in FIG. 7B.

This invention can be applied not only to the differential amplifier 1 or the double differential amplifier 2 explained in the embodiments, but also to a semiconductor integrated circuit having an emitter follower circuit connected with each of a pair of output terminals, such as a filter.

Other embodiments of this invention include semiconductor devices which incorporate an active element such as a bipolar or MOS element, semiconductor devices having a Gilbert-cell structure and requiring symmetry, such as a mixer or an AGC circuit, semiconductor devices used in a high frequency region, semiconductor devices using a SiGe process and semiconductor devices for satellite TV, terrestrial TV and an RF LAN.

Symmetry of the circuit block including the emitter follower circuits is improved to have better circuit characteristics with this invention, since the interconnections from output terminals of the circuit block to the emitter follower circuits are kept from intersecting with each other, are made equal in length and can be shortened, when the emitter follower circuits are disposed close to the circuit block and symmetrically with respect to the center line of the circuit block.

What is claimed is:

1. A semiconductor integrated circuit comprising:
a circuit block having a plurality of semiconductor elements; and
a pair of emitter follower circuits connected with the circuit block including transistors which are disposed in approximation to the circuit block and symmetrically with respect to a center line of the circuit block.

2. The semiconductor integrated circuit of claim 1, wherein each emitter follower circuit comprises a first transistor, a base of which is provided with an output of the circuit block and a second transistor which provides the first transistor with an electric current.

3. The semiconductor integrated circuit of claim 1, wherein the transistors in the emitter follower circuits are disposed in a different orientation from that of transistors in the circuit block by 90 degrees or 270 degrees.

4. The semiconductor integrated circuit of claim 1, wherein the transistors in the emitter follower circuits are disposed parallel to transistors in the circuit block.

5. The semiconductor integrated circuit of claim 4, wherein an emitter, a base and a collector of each of the transistors in the emitter follower circuits are aligned in inverse order to an emitter, a base and a collector of each of the transistors in the circuit block.

6. The semiconductor integrated circuit of claim 4, wherein an emitter, a base and a collector of each of the transistors in the emitter follower circuits are aligned in a same order as an emitter, a base and a collector of each of the transistors in the circuit block.

7. The semiconductor integrated circuit of claim 1, wherein the circuit block comprises a differential amplifier.

8. The semiconductor integrated circuit of claim 2, wherein the circuit block comprises a differential amplifier.

9. The semiconductor integrated circuit of claim 3, wherein the circuit block comprises a differential amplifier.

10. The semiconductor integrated circuit of claim 4, wherein the circuit block comprises a differential amplifier.
